(19) United States
(12) Patent Application Publication
(10) Pub. No.: US 2007/0062451 A1
(43) Pub. Date: Mar. 22, 2007

(54) STABILIZING SYSTEM FOR FILM DEPOSITION

(76) Inventors: Wen-Cheng Hsu, Miaoli County (TW); Kuo-Chin Hung, Changhua County (TW); Chin-Ming Hsu, Tainan City (TW); Hor-Ta Chaung, Hsinchu City (TW); Chung-Jun Cheng, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,692

(22) Filed: Sep. 20, 2005

(51) Int. Cl. C23C 16/00

(52) U.S. Cl. 118/723 I

(57) ABSTRACT

A stabilizing system for a plasma process is provided. The system has a high frequency power source, a plasma chamber, a control circuit for outputting a control signal, first switch element and an impedance matching network. The first switch element has a first, a second and a first switch control terminals, wherein the first and the first switch control terminals are coupled to the control circuit to determines whether the first and the second terminals element are connected or not according to the control signal. The impedance matching network has a first terminal coupled to the plasma chamber, a second terminal coupled to the high frequency power source and a matching control terminal coupled to the second terminal of the first switch element. In this way, whether an impedance matching auto-tune operation for the high frequency power is performed or not is determined based on the control signal.

### BACKGROUND OF THE INVENTION

1. Field of the Invention

The present invention relates to a semiconductor processing device. More particularly, the present invention relates to a stabilizing system for a plasma process.

2. Description of Related Art

In early 20^{th} century, plasma technology has been broadly applied to many fields. With highly development of high-technology industries, such as semiconductor and optoelectronics, etc., the plasma reactor has been widely adopted to fabrication of various devices, such as chip, memory and transistor, etc. In the semiconductor fabrication process, the plasma can be applied to etching, sputtering and chemical vapor deposition.

FIG. 1 is a block diagram showing a conventional semiconductor equipment for film deposition using plasma. The equipment comprises a radio frequency (RF) power source 100, an impedance matching network 102, a low-frequency power source 104, a switch element 106, a control circuit and a plasma chamber 110. A base 112, an upper electrode plate 114, a wafer 116 and a target 118 are further included inside the plasma chamber 100. For a comprehensive description, a control wire CLA and terminals A, B are labeled.

When the equipment is in a clean mode, the control circuit 1 08 outputs a control signal with potential of about 24V through the control wire CLA, so as to control the switch element 106 to connect the RF power source 100 to the terminal A. In this way, plasma is generated in the plasma chamber 110 to clean the wafer 116. At this time, since the control signal on the control wire CLA is larger than 0V, the impedance matching network does not carry out an auto-tune process for the impedance matching.

Alternatively, when the equipment prepares to perform a plasma process, such as a physical vapor deposition (PVD) process, the control circuit 108 outputs a control signal with potential of about 0V through the control wire CLA, so as to control the switch element 106 to connect the RF power source 100 to the terminal B. As a result, the RF power source 100 is in connection with the impedance matching network 102. At this time, the control circuit 108 also outputs a control signal with potential of about 0V through the control wire CLA. Thus, the impedance matching network 102 auto-tunes so as to perform the impedance matching operation to the RF power source 100. The RF power source 1 00 supplies power to the plasma chamber 110 through the impedance matching network 102. Atoms of noble gas in the plasma chamber 110 are ionized to generate plasma. Thereafter, the low-frequency power source 104 applies a bias to the upper electrode plate 114 to attract positive ions, so as to bombard the target 118. In this manner, atoms of the target are deposited onto the surface of the wafer 116.

However, the noise of the control circuit 108 will couple to the impedance matching network 102 through the control wire CLA, and the potential of the 0V control signal on the control wire CLA will be raised, causing an auto-tune failure of the impedance matching network 102. Due to the impedance mismatch, the full power energy generated by the RF power source 100 can not be completely transmitted to the plasma chamber 110. In addition, the reflected energy might reduce the film deposition quality, or even damage the RF power source 100 and other circuits. Furthermore, the equipment always sends warnings because of the auto-tune malfunction. The engineer might misjudge that the equipment requires stop for maintenance, which can cause serious loss in the production yield.

### SUMMARY OF THE INVENTION

According to the foregoing description, an object of the present invention is to provide a stabilizing system for a plasma process. In this way, the impedance matching network can be isolated from noise.

According to the above objects, the present invention provides a stabilizing system for film deposition. The system comprises a high frequency power source, a plasma chamber, a control circuit, a first switch element, an impedance matching network. The high frequency power source is used for supplying a high frequency power. The plasma chamber is used for performing a plasma process. The control circuit for outputting a control signal. The first switch element has a first terminal, a second terminal and a first switch control terminal. The first terminal and the first switch control terminal of the first switch element are coupled to the control circuit to determines whether the first and the second terminals of the first switch element are connected or not according to the control signal. The impedance matching network having a first terminal, a second terminal and a matching control terminal, in which the first terminal is coupled to the plasma chamber, the second terminal is coupled to the high frequency power source and the matching control terminal is coupled to the second terminal of the first switch element. In this manner, whether an impedance matching auto-tune operation for the high frequency power is performed or not can be determined according to the control signal.

According to the stabilizing system of the present invention, the switch element is used for isolation, and therefore, noise will not affect the auto-tune function of the impedance matching network.

### BRIEF DESCRIPTION OF THE DRAWINGS

While the specification concludes with claims particularly pointing out and distinctly claiming the subject matter which is regarded as the invention, the objects and features of the invention and further objects, features and advantages thereof will be better understood from the following description taken in connection with the accompanying drawings.

FIG. 1 is a block diagram showing a conventional semiconductor equipment for film deposition using plasma.

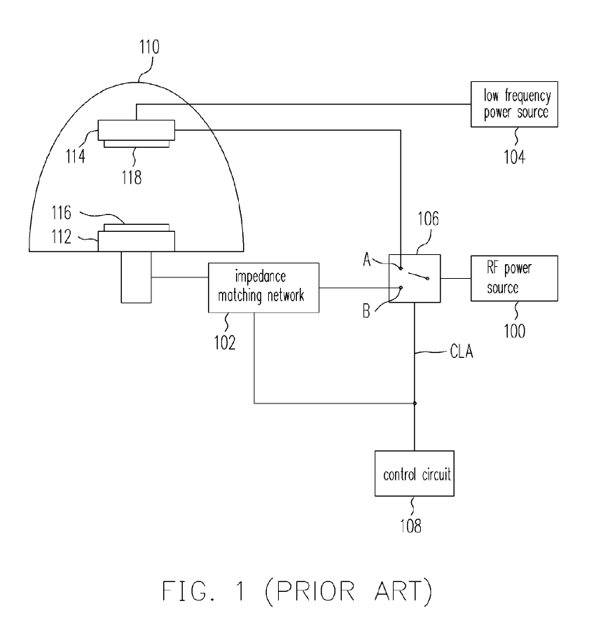

FIG. 2 is a diagram showing a stabilizing system for a plasma process according to one embodiment of the present invention.

FIG. 3 is a diagram showing a switch element of the stabilizing system according to one embodiment of the present invention.

### DESCRIPTION OF THE PREFERRED EMBODIMENT

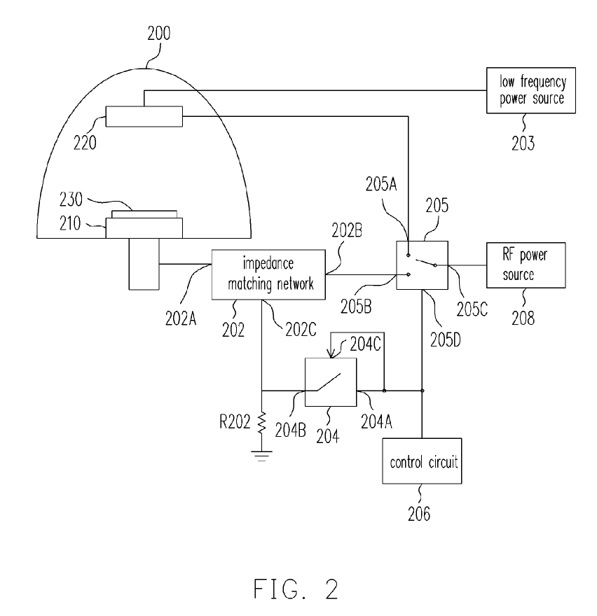

FIG. 2 is a diagram showing a stabilizing system for a plasma process according to one embodiment of the present invention. The system comprises a plasma chamber 200, an impedance matching network 202, a low frequency power source 203, a first switch element 204, a second switch element 205, a control circuit 206 and a high frequency power source (such as an RF power source) 208. Inside the plasma chamber 200, a base 210, an upper electrode 220 and a wafer 230 further included.

According to the embodiment of the present invention, a first terminal 202A of the impedance matching network is coupled to the base 210 inside the chamber 200. A second terminal 204B of the first switch element 204 is coupled to a matching control terminal 202C of the impedance matching network 202. A first terminal 204A and a first switch control terminal 204C are coupled to the control circuit 206. The RF power source 208 is coupled to a third terminal 205C of the second switch element 205, and a second terminal 205B of the second switch element 205 is coupled to a second terminal 202B of the impedance matching network 202. A first terminal 205 A of the second switch element 205 is coupled to the upper electrode 220. A control terminal 205D of the second switch element 205 is coupled to the control circuit 206. The low frequency power source 203 is coupled to the upper electrode 220 inside the plasma chamber 200.

The RF power source 208 is used for supplying a required RF power to the plasma chamber 200 to generate plasma. Energy generated by the low frequency power 203 and the RF power source 208 is supplied to the plasma chamber 200. In this way, plasma generated in the plasma chamber 200 can bombard the surface of the wafer 230 to carry out the film deposition process, the etching process or the clean process for the wafer 230. The control circuit 206 is used for outputting a control signal to determine whether or not the first switch element 204 is turned on or off.

When the equipment is in the clean mode, the control circuit 206 outputs a control signal with a potential of about 24V to control the second switch element 205. The 24V control signal is only an example in the embodiment, not for limiting the scope of the present invention. Then, the RF power source 208 is coupled to the upper electrode plate 220 through the second switch element 205, so as to perform a plasma clean operation. In addition, the first switch element 204 is turned on by the control signal sent from the control circuit 206, and therefore, the control signal is transmitted to the impedance matching network 202. In this way, the auto-tune function of the impedance matching network 202 is not activated by the control signal with a potential of about 24V sent from the control circuit 206.

When the equipment prepares to perform a deposition (for example, physical vapor deposition (PVD)) or an etching process (for example, dry etching), the control circuit 206 outputs a control signal with a potential of about 0V to turn on the second switch element 205. Also, the 0V control signal is only an example in the embodiment, not for limiting the scope of the present invention. Therefore, the RF power source 208 and the impedance matching network 202 are connected through the second switch element 205. At this time, the first switch element 204 is disabled by the OV control signal output from the control circuit 206. Due to disabling the first switch element 204, the noise is not coupled from the control circuit 206 to the impedance matching network 202. In addition, a pull-down resistor R202 can be added to the matching control terminal 202C to lower the potential to 0V, so as to activate the auto-tune function. Therefore, the impedance matching network 202 can stably perform the impedance matching operation for the high frequency power output from the RF power source 208. The RF power source 208 supplies power through the impedance matching network 202 to the plasma chamber 200 to generate plasma.

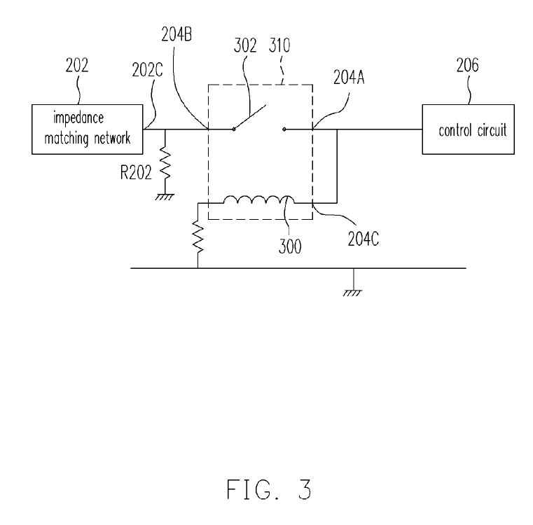

FIG. 3 is a diagram showing a switch element of the stabilizing system according to one embodiment of the present invention. In FIG. 3, a relay 310 is used as an example for the first switch element 204. The relay 310 has a coil 300 and a switch 302. When the control circuit 206 outputs the 24V control signal, the RF power source 208 is not coupled to the matching control terminal 202C of the impedance matching network 202, and the impedance matching network does not need to perform the auto-tune operation. At this time, the 24V control signal passes through the coil 300 of the relay 310, and the switch 302 of the relay is turned on. Hence, the 24V control signal output from the control circuit 206 is transmitted to the matching control terminal 202C of the impedance matching network 202. When the impedance matching network 202 receives the 24V control signal, the auto-tune operation for the impedance match is not performed.

When the control circuit 206 outputs the 0V control signal, the RF power source 208 is coupled to the impedance matching network 202. At this time, the current flowing through the coil 300 of the relay is very small or even no current, and thus the switch 302 of the relay 310 is cutoff. Because the switch 302 is cutoff, the first terminal 204A and the second terminal 204B of the second switch element 204 are not connected and thus noise from the control circuit 206 is not coupled to the impedance matching network 202. In addition, a pull-down resistor R202 can be added to the matching control terminal 202C to lower the potential of the matching control terminal 202C to 0V, so as to activate the auto-tune function to perform the impedance matching operation for the RF power source 208.

According to the stabilizing system of the present invention, the switch element is used for isolation, and therefore, noise will not affect the auto-tune function of the impedance matching network.

While the present invention has been described with a preferred embodiment, this description is not intended to limit our invention. Various modifications of the embodiment will be apparent to those skilled in the art. It is therefore contemplated that the appended claims will cover any such modifications or embodiments as fall within the true scope of the invention.

What is claimed is:

1. A stabilizing system for film deposition, comprising:
a high frequency power source for supplying a high frequency power;
a plasma chamber for performing a plasma process;
a control circuit for outputting a control signal; a first switch element having a first terminal, a second terminal and a first switch control terminal, wherein the first terminal and the first switch control terminal are coupled to the control circuit to determines whether the first and the second terminals of the first switch element are connected or not according to the control signal; and
an impedance matching network having a first terminal, a second terminal and a matching control terminal, wherein the first terminal is coupled to the plasma chamber, the second terminal is coupled to the high frequency power source and the matching control terminal is coupled to the second terminal of the first switch element, and whether an impedance matching auto-tune operation for the high frequency power is performed or not is determined according to the control signal.

2. The stabilizing system of claim 1, wherein the first switch element is a relay.

3. The stabilizing system of claim 1, wherein the high frequency power source is a radio frequency power source.

4. The stabilizing system of claim 1, wherein the chamber is used to perform a clean process.

5. The stabilizing system of claim 4, wherein the chamber is further used to perform a deposition process.

6. The stabilizing system of claim 5, wherein the chamber is further used to perform an etching process.

7. The stabilizing system of claim 4, further comprising a second switch element having a first terminal, a second terminal, a third terminal and a control terminal, wherein the first terminal is coupled to an upper electrode of the plasma chamber, the second terminal is coupled to the second terminal of the impedance matching network, the third terminal is coupled to the high frequency power source, and the control terminal is coupled to the control circuit so as to determine that the first and the second terminals of the second switch element are connected during a clean process or the third and the second terminals of the second switch element are connected during a deposition process according to the control signal.

8. The stabilizing system of claim 6, further comprising a low frequency power source coupled to the plasma chamber for supplying a low frequency power.
